(19) United States
(12) Patent Application Publication
(10) Pub. No.: US 2007/0113787 A1
(43) Pub. Date: May 24, 2007

(54) Plasma process apparatus

(75) Inventors: Tsutomu Higashiura, Nirasaki-shi (JP); Takashi Akahori, Chofu-shi (JP); Satoru Kawakami, Mitsuzawa (JP); Nobuhiro Iwama, Nirasaki-shi (JP)

Correspondence Address: CROWELL & MORING LLP;INTELLECTUAL PROPERTY GROUP, P.O. BOX 14300, WASHINGTON, DC, 20044-4300, US

(73) Assignee: Tokyo Electron Limited, Minato-ku (JP)

(21) Appl. No.: 11/654,007

(22) Filed: Jan. 17, 2007

Related U.S. Application Data
(62) Division of application No. 10/496,361, filed on May 21, 2004.

(30) Foreign Application Priority Data
Dec. 13, 2001 (JP) 2001-380168

(51) Int. Cl. C23F 1/00; C23C 16/00

(52) U.S. Cl. 118/723 E; 156/345.47

(57) ABSTRACT

The upper electrode (15a) and the lower electrode (15b) are installed in the chamber (2) in parallel. Between these electrodes, the upper electrode (15a) is electrically grounded. The lower electrode (15b) is connected to the first RF power generator (13) via the low-pass filter (14) and to the second RF power generator (22) via the high-pass filter (23). Wafer W is held against the upper part of the lower electrode (15b) by the high-temperature electrostatic chuck ESC. By being distributed the first and the second RF electric power from the RF power generators (13) and (22), respectively, plasma is produced near the lower electrode (15b), and the wafer W is processed by the plasma. By these procedures, plasma process apparatus with high efficiency in plasma processing and simple structure can be offered.

### CROSS-REFERENCE TO RELATED APPLICATIONS

This application is a division of U.S. application Ser. No. 10/496,361, filed May 21, 2004, which is the National Phase of International Application PCT/JP2002/013093, filed Dec. 13, 2002. This application claims priority from Japanese patent application Serial No. 2001-380168 filed Dec. 13, 2001, the entire contents of which are expressly incorporated herein by reference.

### TECHNICAL FIELD

The present invention relates to plasma process apparatus that carries out processes such as film formation and etching to workpieces such as semiconductor wafers.

### BACKGROUND ART

Plasma process apparatus is used in the fabrication processes of such as semiconductor substrates and liquid crystal substrates. The apparatus carries out surface treatment on those substrates using plasma. Plasma process apparatus includes, for example, plasma etchers that carry out etching on substrates, and plasma deposition reactors that carry out the process of chemical-vapor deposition (CVD). Among these kinds of plasma process apparatus, those of parallel-plate type are vastly used because they can carry out processes homogeneously and make the structure of equipment relatively simple.

The plasma process apparatus of parallel-plate type has a pair of parallel plate electrodes in the upper and lower sides of a chamber. The lower electrode has a pedestal to hold a workpiece, whereas the upper electrode has multiple gas outlets on the bottom side. The upper electrode is connected to the source of process gases, and process gases are supplied to the space between the two electrodes (plasma-generating space) through the gas outlets during processing. The process gases supplied through the gas outlets are ionized by the radio frequency (RF) electric power applied to the upper electrode. The generated plasma is then pulled near the lower electrode by another RF electric power applied to the lower electrode, the frequency of which is lower than the former. Then, the workpiece located adjacent to the lower electrode is processed with a certain surface treatment by the pulled plasma.

With regard to the plasma process apparatus of parallel-plane type described above, the concentration of plasma produced near the upper electrode is reduced until it reaches the workpiece adjacent to the lower electrode. This reduction of concentration is a major problem because the efficiency of processing deteriorates.

Besides, it is difficult to install pipes for process gases or coolant, the latter of which is for chamber temperature control, through the upper electrode.

The present invention has been made in consideration of the above. And an object thereof is to provide a plasma process apparatus that has high efficiency in plasma processing and that has simple structures.

### DISCLOSURE OF INVENTION

In order to achieve the above object, according to the first aspect of the present invention, there is provided a plasma process apparatus, comprising a chamber (2) having multiple components and inside of which a workpiece is treated with a certain process, first electrode (15a) installed as one of the components and electrically grounded, second electrode (15b) installed as one of the components and supplied with first and second radio frequency electric powers, and a certain area of the chamber (2) containing plasma produced between the first and second electrodes by applying the second radio frequency power to the second electrode (15b).

In the above structure, plasma is mainly produced near the second electrode (15b), since both the first and the second RF power are applied to the second electrode (15b) and the first electrode (15a) is grounded. Therefore, by putting a workpiece near the second electrode (15b), plasma process is carried out without moving plasma and the deterioration of process efficiency due to reduction of plasma concentration is prevented.

Besides, since the first electrode (15a) is grounded and the installation of RF power generators or filters is not necessary, the structure of the plasma process apparatus becomes simple. Therefore, it is easy to have a structure in which pipes for process gases and coolant penetrates through the first electrode (15a).

The above structure may further comprise: a low-pass filter (14) connected between the second electrode (15b) and the first external power generator that distributes the first RF power, a high-pass filter (23) connected between the second electrode (15b) and the second external power generator that distributes the second RF power, and wherein the high-pass filter (23) substantially prevents the first RF power, which is supplied by the first power generator, from passing through, and the low-pass filter (14) substantially prevents the second RF power, which is supplied by the second power generator, from passing through.

By further having this structure, the malfunction of the RF power generators and loss of power are prevented, both of which are due to the leakage of the first RF power of the first RF power generator into the second RF power generator, or vice versa. Therefore, further efficiency of plasma processing is achieved.

The low-pass filter (14) has capacitors (C1 and C2) that are connected in parallel to the first RF power generator and a inductor (L) that passes through the first RF power that is distributed to the second electrode. When the inductor (L) makes parallel resonance circuit with its parasitic capacitance, and the resonant frequency of which is around the frequency of the second RF power, it efficiently blocks the second RF power and prevents the loss of the second RF power, keeping the volume of the inductor (L) small.

According to the second aspect of the present invention, there is provided a plasma process apparatus, comprising a chamber (2) having components and inside of which a workpiece is treated with a certain process, first electrode (15a) installed as one of the components and electrically grounded second electrode (15b) installed as one of the components and supplied with first radio frequency power, a chuck (ESC) that mounts the workpiece adjacent to the second electrode (15b) and used to heat the workpiece cooling channels made of conductor and capacitively coupled to the second electrode (15b) and used to pass through coolant for cooling the chuck (ESC) and a certain area of the chamber (2) containing plasma produced between the first and second electrodes by applying second radio frequency power to the second electrode (15b) via the cooling channels.

In the above structure, plasma is also mainly produced near the second electrode (15b), since both the first and the second RF power is applied to the second electrode (15b) and the first electrode (15a) is grounded. Therefore, by putting a workpiece near the second electrode (15b), plasma process is carried out without moving plasma and the deterioration of process efficiency due to reduction of plasma concentration is prevented.

Besides, since the first electrode is grounded and the installation of RF power generators or filters is not necessary, the structure of the plasma process apparatus becomes simple. Therefore, it is easy to have a structure in which pipes for process gases and coolant penetrates through the first electrode (15a).

In addition, in the above structure, the second RF power is distributed to the second electrode (15b) without using wire made of high melting point metal, which generally has high resistivity. Therefore, loss of the second RF power is reduced and process with high efficiency in use of RF power is achieved.

The above structure may further comprise a low-pass filter (14) connected between the second electrode (15b) and the first external power generator that distributes the first RF power, a high-pass filter (23) connected between the cooling channels and the second external power generator that distributes the second RF electric power, and wherein the high-pass filter (23) substantially prevents the first RF electric power, which is distributed by the first power generator, from passing through, and the low-pass filter (14) substantially prevents the second RF electric power, which is distributes by the second power generator, from passing through.

By further having this structure, power loss is prevented, which is due to the leakage of the first RF power of the first RF power generator into the second RF power generator, or vice versa. Therefore, further efficiency of plasma processing is achieved.

In addition, in the above structure, the low-pass filter (14) has capacitors (C1 and C2) that are connected in parallel to the first RF power generator and an inductor (L) that passes through the first RF power that is distributed to the second electrode. When the inductor (L) makes parallel resonance circuit with its parasitic capacitance, and the resonant frequency of which is around the frequency of the second RF power, it efficiently blocks the second RF power and prevents the loss of the second RF power, keeping the volume of the inductor (L) small.

As described above, the second RF power is distributed to the second electrode (15b) without using wire made of high melting point metal. Besides, the melting point of the conductor used in the cooling channels can be lower than that of the conductor used in the second electrode (15b) or that of the wire used to distribute the first RF power to the second electrode (15b). Therefore, the resistivity of the conductor used in the cooling channels is generally lower than that of the conductor used in the second electrode (15b).

According to the third aspect of the present invention, there is provided a plasma process apparatus, comprising a chamber (2) having multiple components and inside of which a workpiece is treated with a certain process, an electrode installed as one of the components an impedance matching circuit surface-mounted on the electrode and connecting the electrode with the external radio frequency power generator and a certain area of the chamber (2) contains plasma produced between the electrodes by applying radio frequency power to the electrodes.

In the above structure, loss of the RF power that is distributed by the RF power generator is reduced, because the impedance matching circuit is surface-mounted on the electrode. Therefore, the process applied to the workpieces can be made efficient. Besides, since the impedance matching circuit is surface-mounted on the electrode, extra equipment such as boxes to store the circuit is not needed. Thus, the structure of the plasma process apparatus becomes simple, and it is easy to have a structure in which pipes for process gases and coolant penetrates through the electrode.

The impedance matching circuit includes surface-mounted passive elements such as capacitors and inductors (L).

### BRIEF DESCRIPTION OF DRAWINGS

These objects and other objects and advantages of the present invention will become more apparent upon reading of the following detailed description and the accompanying drawings in which:

FIG. 1 shows the structure of the plasma process apparatus for the first embodiment of the present invention.

FIG. 2 shows an example of the low-pass filter installed in the plasma process apparatus of FIG. 1.

FIG. 3 shows the baffle of the plasma process apparatus of FIG. 1.

FIG. 4 shows a variation of the low-pass filter.

FIG. 5 shows the structure of the plasma process apparatus for the second embodiment of the present invention.

FIG. 6 shows a part of the structure of the plasma process apparatus for the third embodiment of the present invention.

### BEST MODE FOR CARRYING OUT THE INVENTION

The plasma process apparatus of the present invention comprises: a chamber (2) includes multiple components and inside of which a workpiece is treated with a certain process; the first electrode (16a) that is installed as one of the components and is electrically grounded; the second electrode (15b) that is installed as one of the components and is supplied with the first and the second RF electric power; and wherein a certain area of the chamber (2) contains the plasma produced between the first and the second electrodes by applying the second RF power to the second electrode (15b).

### First Embodiment

Details of an embodiment of the present invention will be described below using attached figures. In this embodiment of the present invention, plasma deposition reactors that carry out the process of chemical-vapor deposition (CVD) will be described as an example of the plasma process apparatus (equipment).

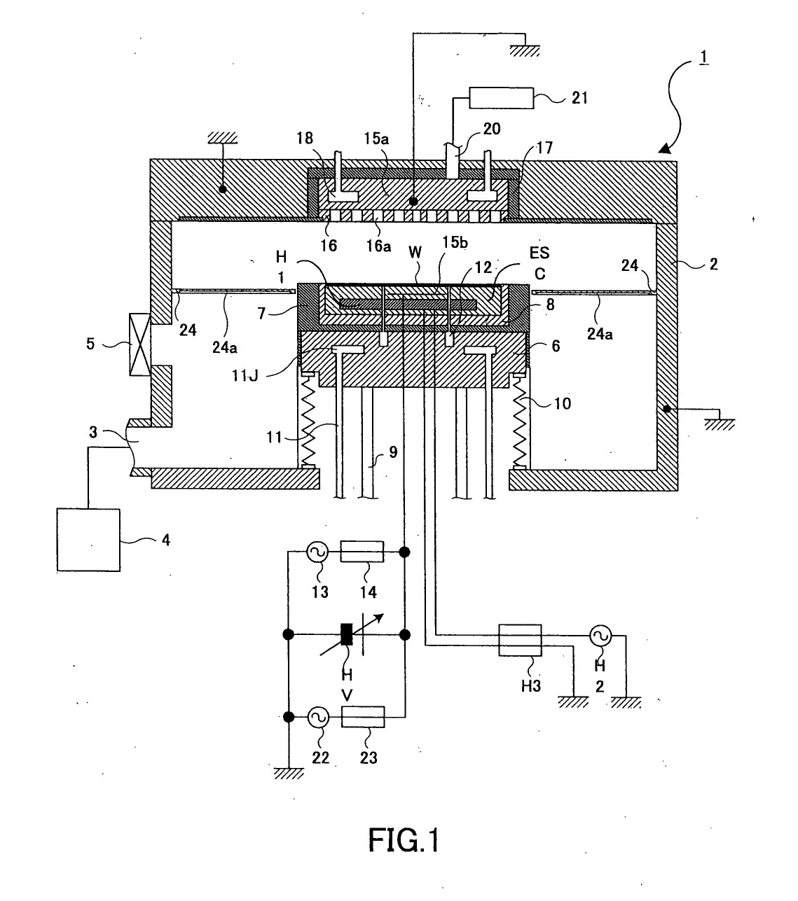

FIG. 1 shows the structure of the plasma process apparatus for the first embodiment of the present invention. The plasma process apparatus 1 for the first embodiment of the present invention is constructed as that of parallel-plate type, which has a pair of parallel plate electrodes in the upper and lower sides of a chamber. The equipment has a function to form films, e.g. of SiOF, on the surface of semiconductor wafers (hereafter referred to as the wafer W).

As shown in FIG. 1, the plasma process apparatus has a cylindrical chamber 2. The chamber 2 is made of conductive materials such as aluminum processed with anodic oxide coating (Alumite). The chamber 2 is electrically grounded.

There is a vent 3 at the bottom part of the chamber 2. The vent 3 is connected to an exhaust system 4 equipped with vacuum pumps such as turbo-molecular pumps. The exhaust system 4 evacuates the chamber 2 to a certain pressure, for example less than 0.01 Pa. Besides, a gate valve 5 is installed in the sidewall of the chamber 2. With the gate valve 5 opened, the wafer W is carried between the chamber 2 and the load-lock chamber, which is located next to the chamber 2 (not shown).

A pseudo-cylindrical susceptor holder 6 is put on the bottom of the chamber 2. On the susceptor holder 6 lies a susceptor 8 to put the wafer W. The interface between the susceptor holder 6 and the susceptor 8 is insulated with an insulator 7 such as aluminum nitride. In addition, the susceptor holder 6 is connected to an elevator, which is installed in the bottom part of the chamber 2 (not shown), via a shaft 9, and it can move up and down.

The center-top part of the susceptor 8 is molded into a convex disk, upon which the high-temperature electrostatic chuck ESC is mounted. The high-temperature electrostatic chuck ESC has the shape similar to the wafer W, and it has the lower electrode 15b and a heater H1 therein. The lower electrode 15b is made of a conductor with high melting point, such as molybdenum. The heater H1 consists of, for example, Nichrome wire.

The lower electrode 15b is connected to a direct-current power generator HV via wire made of a conductor with high melting point such as molybdenum. The wafer W put on the susceptor 8 is held against the high-temperature electrostatic chuck ESC by an electrostatic force, by applying the direct-current voltage generated by the direct-current power generator HV to the lower electrode 15b.

In addition, the lower electrode 15b is connected to the first RF power generator 13 via the low-pass filter 14 and the second RF power generator 22 via the high-pass filter 23. Both RF power generators are connected to the direct-current power generator HV in parallel.

The frequency of the first RF power generator 13 has range of 0.1˜13 MHz. The application of this frequency band is effective, for example, in reducing damage to the workpieces.

The frequency of the second RF power generator 22 has range of 13˜150 MHz. By applying these high frequencies, plasma can be produced in preferable dissociation state and in high density within the chamber 2.

The low-pass filter 14 substantially prevents the second RF electric power, which is distributed by the second power generator 22, from passing through. Therefore, leakage of the second RF power generated by the second RF power generator 22 into the first RF power generator 13, and subsequent power loss, can be prevented.

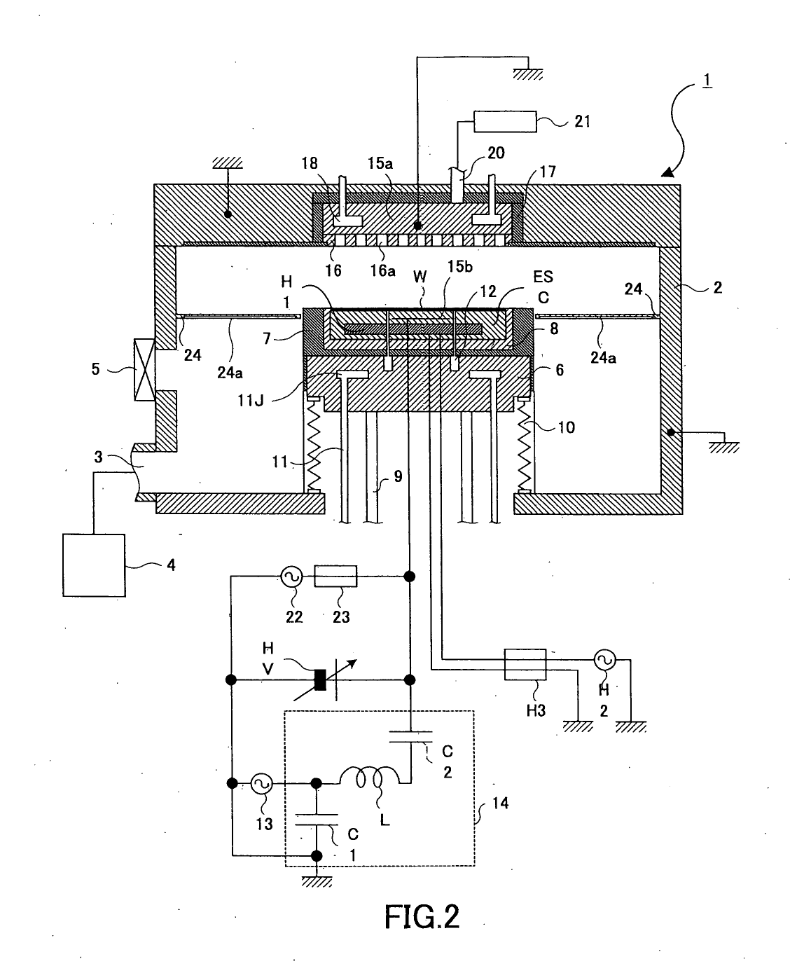

Specifically, the low-pass filter 14 consists of, for example, a capacitor C1 and an inductor L. As shown in FIG. 2, one end of the inductor L is connected to the first RF power generator 13, and the other end of it is connected to the lower electrode 15b via a coupling capacitor C2. Besides, one end of the capacitor C1 is connected to the joint of the inductor L and the first RF power generator 13, and the other end of it is grounded.

The high-pass filter 23 consists of, for example, a capacitor placed between the second RF power generator 22 and the lower electrode 15b. The high-pass filter 23 substantially prevents the first RF power, which is generated by the first power generator 13, from passing through. Therefore, the leakage of the first RF power generated by the first RF power generator 13 into the second RF power generator 22, and subsequent power loss, can be prevented.

A heater H1 is connected to a heater power generator H2 that consists of, e.g. commercial power generator, via a low-pass filter H3. The high-temperature electrostatic chuck ESC is heated by applying voltage generated by the heater power generator H2. Here, the low-pass filter H3 is used to prevent the RF electric power generated by the first or the second RF power generator from leaking into the heater power generator H2.

The center-bottom part of the susceptor holder 6 is covered by, for example, a bellows 10 made of stainless steel. The bellows 10 separates into two parts: one is a vacuum part in the chamber 2; the other is an atmosphere-exposed part. The upper and the lower part of the bellows 10 are screwed to the bottom surface of the susceptor holder 6 and to the floor of the chamber 2, respectively.

Inside of the susceptor holder 6 is a lower cooling channels 11. The lower cooling channels 11 circulate coolant such as Fluorinert. By this procedure, the temperature of the susceptor 8 and that of the surface of the wafer W is controlled preferably.

The lower cooling channels 11 are made of conductors. The upper part of them, which is near the susceptor 8, constitutes a jacket 11J that circulates coolant around the interface of the susceptor holder 6 and the insulator 7.

There are lift pins 12 at the susceptor holder 6. The lift pins 12 are used for delivering the semiconductor wafer W, and that can be raised or lowered by a cylinder (not shown).

The upper electrode 15a is located above the susceptor 8, being parallel with it. The upper electrode 15a is grounded, and the lower side of it has a plate electrode 16, which is made of e.g. aluminum and has multiple gas outlets 16a. The ceiling of the chamber 2 supports the upper electrode 15a, via the insulator 17. There are upper cooling channels 18 inside the upper electrode 15a. The upper cooling channels 18 circulate coolant such as Fluorinert, controlling the temperature of the upper electrode 15a preferably.

In addition, the upper electrode 15a is equipped with the gas outlet 20, which is connected to the process gas source 21 located outside the chamber 2. Process gases from the process gas source 21 are distributed via the gas outlet 20 to the hollow space inside the upper electrode 15a (not shown). The supplied process gases disperse in the hollow space, and then they flow out of the gas outlets 16a toward the wafer W. Various kinds of gases can be used as process gases. In the case of SiOF film forming, the following conventionally used gases can be used: SiF4, SiH4, O2, NF3, NH3 as reaction gases, and Ar as a dilution gas.

The sidewall of the chamber 2 is equipped with a baffle 24. The baffle 24 is made of a conductor such as aluminum processed with anodic oxide coating (Alumite). It is a disk-shaped component with a hole at the center, and it has a structure that the susceptor 8 penetrates through the center hole.

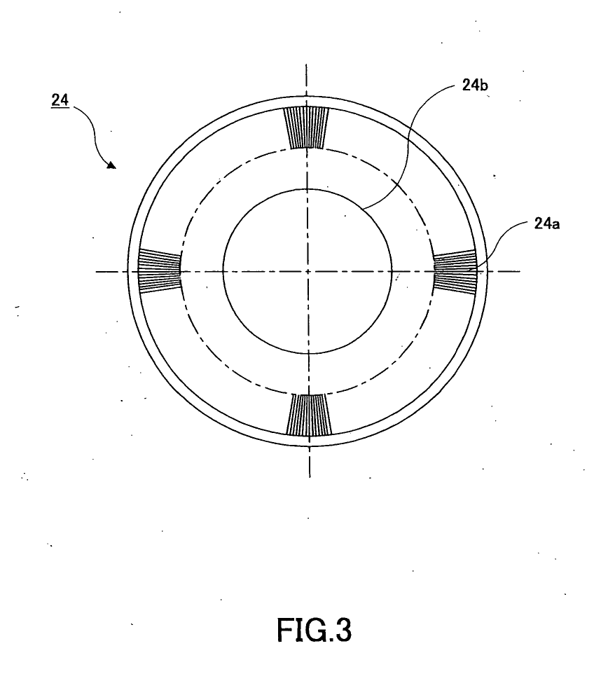

FIG. 3 shows the top view of the baffle 24. As shown in FIG. 3, there is a hole 24b at the center of the baffle 24, and in the circumference of the hole lies multiple radial slits 24a. Now, the slit 24a is a rectangle-shaped slit that is bored vertically through the baffle 24. The width of the slit 24a is set to 0.8˜1.0 mm, in order to block plasma while making gases pass through. The hole 24b has nearly the same area as that of the wafer W.

During processing, the inner edge of the hole 24b is located immediately adjacent to the outer edge of the wafer W. In addition, the slits 24a of the baffle 24 are located below the bottom surface of the wafer W (i.e. in vent side). Therefore, the treatment surface of the wafer W is exposed to the plasma produced between the susceptor 8 and the upper electrode 15a through the hole 24b of the baffle 24. At this point, the space where plasma is produced is determined by the upper part of the chamber 2 and the plate electrode 16 for the upper boundary, and by the wafer W and the baffle 24 for the lower boundary. Then, the plasma concentration is kept constant.

The baffle 24 also has a function to return a part of the RF power applied to the lower electrode 15b, to the first and the second RF power generators 13 and 24, respectively. Specifically, the return current, which originates in the RF power applied to the lower electrode 15b by the first and the second RF power generators 13 and 22, returns to the respective RF power generator via the baffle 24 and the grounded sidewall of the chamber 2.

The behavior of the plasma process apparatus in the above structure will be described below using FIG. 1, in the case of being used for forming SiOF film on the wafer W.

At first, the susceptor holder 6 is moved to the position where the wafer W can be carried in, by the elevator that is not shown. After the gate valve is opened, a carrier arm that is not shown carries the wafer W in the chamber 2. The wafer W is put on the lift pin 12 that is protruding from the susceptor 8. Then the lift pin 12 retracts, and the wafer W is put on the susceptor 8, being clamped in place by an electrostatic force of the high-temperature electrostatic chuck ESC. After the gate valve 5 is closed, the exhaust system 4 evacuates air from the chamber 2 until a certain degree of vacuum is achieved. Then, the elevator that is not shown lifts up the susceptor holder 6.

In this condition, the temperature of the susceptor 8 is kept at a certain level, for example 50° C., by circulating coolant through the lower cooling channels 11, and/or supplying electric power to the heater H1 from the heater power generator H2. On the other hand, the exhaust system 4 further evacuates air from the chamber 2 via the vent 3, and it brings the chamber into high vacuum state, for example 0.01 Pa.

Then, process gases such as SiF4, SiH4, O2, NF3, NH3 and a dilution gas of Ar are distributed into the chamber 2 from the process gas source 21, with their flow controlled at a certain flow rate. The process gases and the carrier gas that are distributed to the upper electrode 15a flow out of the gas outlets 16a of the plate electrode 16, and uniformly spread over the wafer W.

After that, RF power with frequency of, e.g., 50˜150 MHz is applied to the lower electrode 15b by the second RF power generator 22. By this procedure, RF electric field is generated between the upper electrode 15a and the lower electrode 15b, and the process gases provided via the upper electrode 15a are ionized and plasma is created. On the other hand, RF power with frequency of, e.g., 1˜4 MHz is applied to the lower electrode 15b by the first RF power generator 13. As a result, ions in the plasma are pulled toward the susceptor 8, and the concentration of the plasma adjacent to the surface of the wafer W increases. As described above, plasma of the process gases are created by the generation of RF electric field between the upper electrode 15a and the lower electrode 15b. Subsequently, SiOF film is formed on the surface of the wafer W, by chemical reactions occurred on the wafer surface due to plasma.

As described above, in the plasma process apparatus of the first embodiment of the present invention, both of the RF power generated by the first and the second RF power generators are applied to the lower electrode 15b, while the upper electrode 15a is grounded. Therefore, plasma is produced mainly near the lower electrode, and reduction of the plasma concentration until it reaches the wafer W can be prevented. As a result, deterioration of the film-forming process efficiency can be prevented.

Besides, since the first electrode 15a is grounded and any RF power generators or filters are not installed around the first electrode, the structure of the plasma process apparatus becomes simple. Therefore, it is easy to have a structure in which pipes for process gases and coolant penetrates through the first electrode 15a.

By the way, the structure of the plasma process apparatus 1 is not limited to the one described above.

For example, the baffle 24 may have a structure in which an insulator such as ceramics is installed between the outer side of the baffle and the inner wall of the chamber 2. In this case, by limiting electrical contact between the baffle and the inner wall of the chamber 2, further reduction of RF power loss can be achieved.

In addition, the material of the baffle 24 is not limited to the aluminum processed with anodic oxide coating (Alumite). Other materials such as alumina and yttria may be used, provided that they are conductors and have high plasma resistance. By meeting these conditions, baffle 24 acquires high plasma resistance and the plasma process apparatus 1 as a whole achieves high maintainability.

In the above embodiment of the present invention, the plasma process apparatus of parallel-plate type for forming SiOF film on semiconductor wafers is described. However, workpieces are not limited to semiconductor wafers, and this equipment can be used to make other devices such as liquid crystal display. Besides, films to be formed may be other materials such as SiO2, SiN, SiC, SiCOH, and CF.

The plasma processing applied to workpieces is not limited to the film forming. Other processes such as etching can be carried out by the present invention. Furthermore, suitable plasma process apparatus is not limited to that of parallel-plate type. Other plasma process apparatus such as magnetron type thereof is also applicable, provided that it has electrodes inside the chamber.

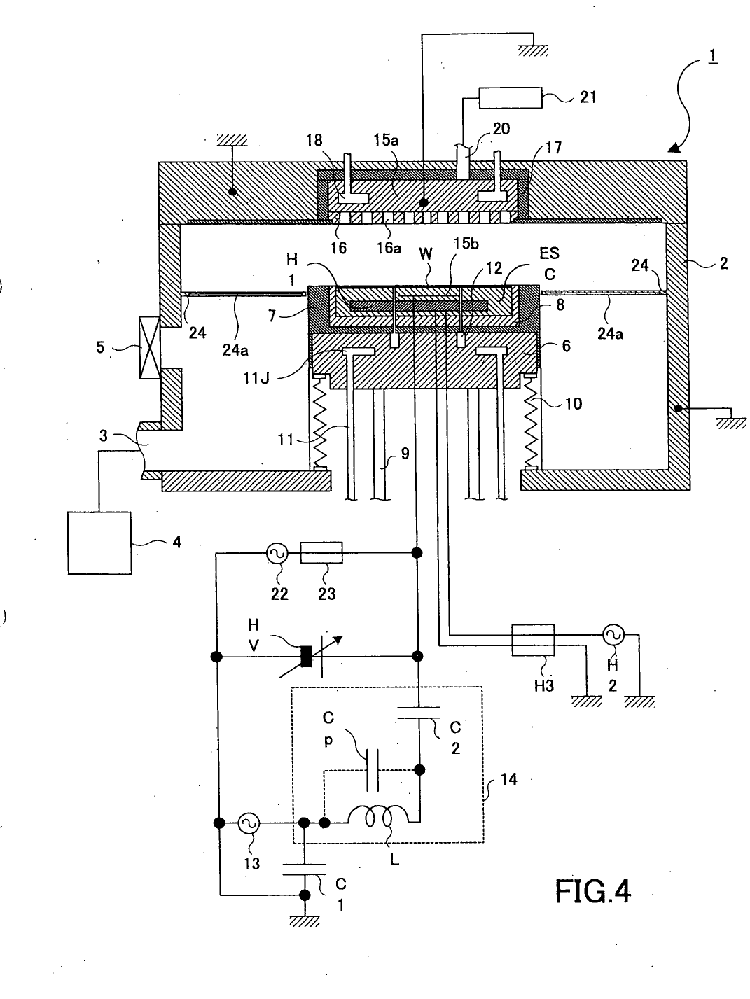

As shown in FIG. 4, the inductor L of the low-pass filter may form a parallel resonant circuit with the wiring capacitance (or other parasitic capacitances) Cp created by the coils of the inductor L. In this case, the resonance frequency of the parallel resonant circuit must be nearly equal to that of the RF electric power generated by the second RF power generator 22.

By applying the structure of the low-pass filter 14 shown in FIG. 4, power loss can be prevented by efficiently limiting the leakage of the RF power generated by the second RF power generator 22, keeping the volume of the inductor L small.

### Second Embodiment

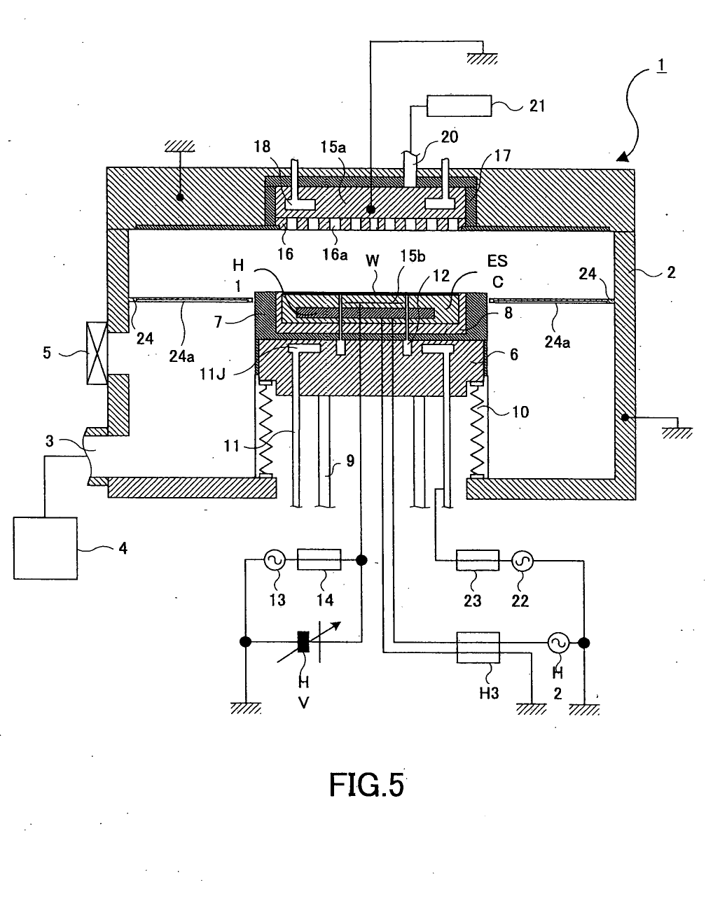

The second embodiment of the present invention will be described below using FIG. 5. The symbols in FIG. 5 are the same as those of FIG. 1 for the same components.

As shown in FIG. 5, the structure of the plasma process apparatus 1 is practically the same as that of the first embodiment of the present invention, except those points described below. The structure of the low-pass filter 14 can be the same as, e.g., that shown in FIG. 4.

In the plasma process apparatus 1 shown in FIG. 5, the jacket 11J and the lower electrode 15b that is embedded in the high-temperature electrostatic chuck ESC are capacitively coupled. In other words, the jacket 11J and the lower electrode 15b constitute the electrodes of a capacitor.

The second RF power generator 22 is connected to the lower cooling channels 11 through the high-pass filter 23. The RF power generated by the second RF power generator 22 is applied to the lower electrode 15b via the capacitor composed of the jacket 11J and the lower electrode 15b.

In the plasma process apparatus of the second embodiment of the present invention shown in FIG. 5, the RF power generated by the second RF power generator 22 is distributed to the lower electrode 15b without using wire made of high melting point metal, which generally has high resistivity. Therefore, loss of the RF power can be reduced, and plasma processing with further high efficiency in use of RF power can be achieved.

### Third Embodiment

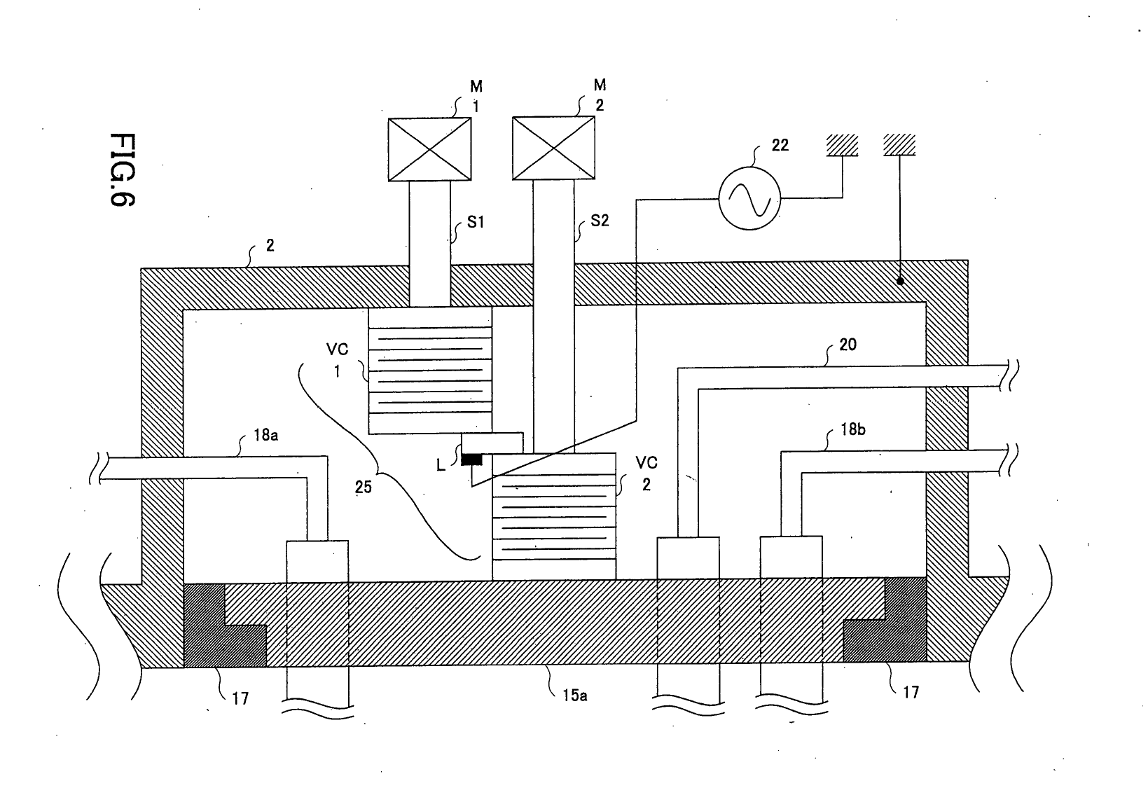

The third embodiment of the present invention will be described below using FIG. 6. FIG. 6 shows a cross section of a part of the plasma process apparatus for the third embodiment of the present invention. The symbols in FIG. 6 are the same as those of FIG. 1 for the same components.

The structure of the plasma process apparatus 1 in FIG. 6 is practically the same as that of FIG. 1, except those points described below. As shown in FIG. 6, in this plasma process apparatus 1, the upper electrode 15a is not grounded. Alternatively, it is connected to the second RF power generator 22 via the matching circuit 25, which is surface-mounted on the upper side (opposite to the inside of the chamber 2) of the electrode 15a. In addition, there is a gap between the upper electrode 15a and the chamber 2 to store the matching circuit 25. The matching circuit 25 consists of variable capacitors VC1 and VC2, and an inductor L, as shown in FIG. 6.

Each of the variable capacitors VC1 and VC2 consists of a rotor and a stator. The stator of the variable capacitor VC1 is mounted on the inner wall of the insulator 17. The rotor of the variable capacitor VC 1 is connected to that of the variable capacitor VC 2, via the inductor L. The stator of the variable capacitor VC 2 is surface-mounted on the center part of the upper electrode 15a, without using lead wire. The first RF power generator 13 is connected to the joint of the variable capacitor VC1 and the inductor L.

The variable capacitor VC2 is not necessarily mounted on the center part of the upper electrode 15a. However, it is desirable to mount the variable capacitor VC2 on the center part of the upper electrode 15a, in order to make the RF power that is generated by the second RF power generator 22 uniformly applied on the first electrode 15a.

The rotor of the variable capacitor VC1 has a shaft S1, which corresponds to the axis of the rotor. The shaft S1 is connected to a motor M1, which is used to rotate the shaft S1. The capacitance of the variable capacitor VC1 can be varied, by operating a control circuit (not shown) to drive the motor M1 to rotate the shaft S1.

Similarly, the rotor of the variable capacitor VC2 has a shaft S2, to which a motor M2 is connected. The capacitance of the variable capacitor VC2 can be varied, by operating a control circuit (not shown) to drive the motor M2 to rotate the shaft S2.

In addition, the upper cooling channels 18 include an upper coolant outlet-pile 18a and an upper coolant drainpipe 18b. As shown in FIG. 6, both of the upper coolant outlet-pipe 18a and the upper coolant drainpipe 18b are installed in the gap described above, connecting the inside of the upper electrode 15a and the outside of the chamber 2. The gas outlet 20 is also installed in the gap, connecting the inside of the upper electrode 15a and the process gas source 21.

When forming SiOF films using the plasma process apparatus with the structure shown in FIG. 6, the operator manipulates the above mentioned control circuits to drive the motors M1 and M2. Then, by adjusting the capacitances of the variable capacitors VC 1 and VC2, the operator carries out impedance matching.

Then, the process gases and the carrier gas are supplied into the upper electrode 15a, and they flow out of the gas outlets 16a of the plate electrode 16 towards the wafer W. With the gases flowing, the RF power with frequencies of, e.g., 50˜150 MHz distributed from the second RF power generator 22 is applied to the upper electrode 15a. By this procedure, RF electric field is created between the upper electrode 15a and the lower electrode 15b, and the process gases supplied from the upper electrode 15a is ionized, producing plasma. On the other hand, the RF electric power with frequencies of, e.g., 1˜4 MHz is applied to the lower electrode 15b from the first RF power generator 13. By this procedure, active species in the plasma is pulled near the susceptor 8, increasing the plasma concentration adjacent to the surface of the wafer W. As described above, plasma of the process gases are created by the generation of RF electric field between the upper electrode 15a and the lower electrode 15b. Subsequently, SiOF film is formed on the surface of the wafer W, by chemical reactions occurred on the wafer surface due to plasma.

With regard to the plasma process apparatus 1 shown in FIG. 6, loss of the RF power generated by the second RF power generator 22 can be reduced and the plasma process becomes more efficient, because the matching circuit 25 is surface-mounted on the upper electrode 15a. Besides, since the matching circuit 25 is surface-mounted, extra equipment such as boxes to store the matching circuit 25 is not needed. Thus, the structure of the plasma process apparatus becomes simple, and it is easy to install pipes for process gases and coolant penetrating through the electrode.

The present invention provides plasma process apparatus that has high efficiency in plasma processing and that has simple structure. This application is based on Japanese Patent Application No. 2001-380168 filed on Dec. 13, 2001 and including specification, claims, drawings and summary. The disclosure of the above mentioned Japanese Patent Application is incorporated herein by reference in its entirety.

### INDUSTRIAL APPLICABILITY

The present invention relates to plasma process apparatus to conduct plasma processes such as film forming and etching, which is applied to workpieces such as semiconductor wafers.

1. A plasma apparatus, comprising:
a chamber in which a workpiece is treated with a certain process;
a susceptor holder provided in the chamber;
a susceptor provided on the susceptor holder and on which a workpiece to be treated is mounted;
a cooling channel provided in said susceptor holder and through which coolant is circulated to control the temperature of the susceptor;
a first electrode provided over said susceptor;
a second electrode installed in said susceptor or in said susceptor holder and supplied with first and second radio frequency electric powers;
an electrostatic chuck provided adjacent to said second electrode for holding said workpiece by an electrostatic force; and
an area within said chamber containing plasma produced between said first electrode and said susceptor by applying said first and second radio frequency powers to said second electrode.

2. The plasma process apparatus according to claim 1, wherein the cooling channel is made of a conductor.

3. The plasma process apparatus according to claim 2, wherein said cooling channel is connected to a radio frequency power generator and serves as said second electrode.

4. The plasma process apparatus according to claim 1, wherein the cooling channel has a jacket that circulates coolant around the susceptor holder.

5. The plasma process apparatus according to claim 1, further comprising an insulating layer formed between said susceptor and said susceptor holder.

6. The plasma process apparatus according to claim 1, wherein said second electrode is connected to a direct-current power generator.
